(19) United States
(12) Patent Application Publication
(10) Pub. No.: US 2025/0043416 A1
(43) Pub. Date: Feb. 6, 2025

(54) PROTECTED METALLIC COMPONENTS, REACTION CHAMBERS INCLUDING PROTECTED METALLIC COMPONENTS, AND METHODS FOR FORMING AND UTILIZING PROTECTED METALLIC COMPONENTS

(71) Applicant: ASM IP Holding B.V., Almere (NL)

(72) Inventors: Iordan Iordanov, Tempe, AZ (US); Osama Khalil, Phoenix, AZ (US); Allen D'Ambra, Phoenix, AZ (US)

(21) Appl. No.: 18/787,053

(22) Filed: Jul. 29, 2024

Related U.S. Application Data
(60) Provisional application No. 63/529,861, filed on Jul. 31, 2023.

(51) Int. Cl. C23C 16/40; C23C 16/02; C23C 16/455; C23C 16/56

(52) U.S. Cl. CPC C23C 16/4404; C23C 16/40; C23C 16/4407; C23C 16/45523

(57) ABSTRACT

Protected metallic components and reaction chambers including protected metallic components are disclosed. Exemplary methods for forming and utilizing protected metallic components are also disclosed. Protected metallic components include a conformal protective layer disposed over a non-planar surface of a metallic core.

### CROSS-REFERENCE TO RELATED APPLICATIONS

This application claims priority to U.S. Provisional Patent Application Ser. No. 63/529,861 filed Jul. 31, 2023 titled PROTECTED METALLIC COMPONENTS, REACTION CHAMBERS INCLUDING PROTECTED METALLIC COMPONENTS, AND METHODS FOR FORMING AND UTILIZING PROTECTED METALLIC COMPONENTS, the disclosure of which is hereby incorporated by reference in its entirety.

### FIELD

The present disclosure relates to methods and apparatus for the manufacture of electronic devices. More particularly, the disclosure relates to protected metallic components, and reaction chambers including protected metallic components. In addition the disclosure relates to methods for forming and utilizing protected metallic components.

### BACKGROUND

In the manufacture of integrated devices, thin layers are deposited or formed on substrates in a reaction chamber or reactor, for example, by chemical vapor deposition (CVD) or atomic layer deposition (ALD). In these deposition processes, the deposited layers are also deposited on other surfaces, for example, on components within the interior of the reaction chamber, the walls of the reaction chamber, and other exposed (e.g., wetted) surfaces within the reaction chamber. Over time, these layers, commonly referred to as “parasitic layers”, accumulate and build up, eventually flaking, shedding, and/or delaminating particles from the wetted surfaces within the reaction chamber. Particles that land on a surface of a substrate, for example, either falling on the surface or carried in a gas stream, can cause problems in the manufacturing process, for example, by reducing the yield and/or reproducibility of the process. Periodically cleaning the contaminants from the reaction chamber can reduce these problems.

One method for cleaning the components within the reaction chamber is by in situ etching cycles using one or more cleaning cycles of suitable etchants. However, in some cases in-situ etching exhibits one or more drawbacks, for example, significantly etching the components of within the reaction chamber. Consequently, in some cases, in-situ cleaning is not feasible.

Another option for cleaning the components within the reaction chamber is ex-situ cleaning, in which the contaminated components are removed from service for cleaning. “Bead blasting” is a form of ex-situ cleaning by mechanical abrasion in which a stream of an abrasive grit, for example, alumina, zirconia, glass, silica, silicon carbide (SiC), or other suitable material, is impinged against a surface-to-be-cleaned, for example, using a high-pressure fluid stream. Bead blasting has several shortcomings, for example, damage can be caused to the reaction chamber components by the cleaning process, thereby reducing their lifetimes. Bead blasting is a “line of sight” process, resulting in difficultly in cleaning high aspect ratio components. Due to an inability to visually monitor the removal of the contaminant(s), an endpoint is not apparent, such that, when the contaminant is removed and the underlying material is reached; there is a chance of missing a contaminated area. Bead blasting can also cause contamination of the cleaned part by the abrasive material. Contaminants that are as hard or harder than the abrasive material cannot easily be removed by bead blasting. Bead blasting also entails high cost and low reproducibility. Accordingly, improved components for use within a reaction chamber are desired, as well as methods for forming and utilizing the improved components.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to protected metallic components, deposition apparatus including protected metallic components, and methods for forming and utilizing protected metallic components. As set forth in more detail below, protected metallic components and methods for forming and utilizing protected metallic components described herein can be used during the manufacture of electronic devices. Such protected metallic components and method for forming and utilizing the protected metallic components can extend the lifetime of the metallic component, reduce the complexity of removing a parasitic layer formed on the metallic component, and prevent damage to the metallic component during the process to remove a parasitic layer formed over the metallic component. By way of example, the protected metallic components and methods for forming and utilizing protected metallic components described herein can be used in a reaction chamber configured for the deposition a metal oxide layer. In such cases, the deposition of a metal oxide can include depositing a hafnium oxide on a substrate and thereby forming a parasitic layer of hafnium oxide on the metallic components within the reaction chamber. The metallic components employed within the reaction chamber can have similar etching properties to that of hafnium oxide, thereby making the selective removal of the parasitic hafnium oxide layer more complex due to the similar etching characteristics of the parasitic hafnium oxide layer and the metallic component. By forming a protective layer with different etching characteristics to the hafnium oxide parasitic layer, the metallic component can be cleaned to remove the parasitic layer without etching and damaging the metallic component.

In accordance with examples of the disclosure, a protected metallic component for use within a wetted region of an interior of a reaction chamber is provided. In accordance with examples of the disclosure, the protected metallic component includes a metallic core fabricated from a material selected from a group consisting of titanium, titanium alloys, nickel alloys, stainless steel, and aluminum. In accordance with examples of the disclosure, the metallic core includes a non-planar surface. In accordance with examples of the disclosure, a conformal protective layer is disposed directly on the non-planar surface, the conformal protective layer having an average layer thickness between 20 nm and 300 nm and a step-coverage over the non-planar surface greater than 90%. In accordance with examples of the disclosure, the protected metallic component comprises a material selected from a group consisting of metals, metal oxides, and metal carbides. In accordance with examples of the disclosure, the conformal protective layer comprises a metal oxide selected from a group consisting of aluminum oxides, zirconium oxides, and tantalum oxides. In such cases, the conformal protective layer has a partially crystalline structure. Further in such cases, the conformal protective layer can be an aluminum oxide layer having a density greater 3 g/cm³. Additionally in such cases, the conformal protective layer can be a zirconium oxide layer having a density greater 5 g/cm³. In accordance with additional examples of the disclosure, the conformal protective layer comprises a metal oxide selected from a group consisting of aluminum oxides, silicon oxides, yttrium oxides, and zirconium oxides. In such cases, the conformal protective layer has an amorphous structure. Additionally in such cases, the conformal protective layer can have a porosity of between 1% and 10%.

In accordance with additional examples of the disclosure, a deposition apparatus is provided. The deposition apparatus includes a reaction chamber and a protected metallic component disposed with the reaction chamber. The protected metallic component is fabricated from a material selected from a group consisting of titanium, titanium alloys, nickel alloys, stainless steel, and aluminum. In addition, the protected metallic component includes a non-planar surface. A conformal protective layer is disposed directly on the non-planar surface of the metallic core, the conformal protective layer having an average layer thickness between 20 nm and 300 nm and a step-coverage over the non-planar surface greater than 90%. In accordance with examples of the disclosure, the conformal protective layer has a partially crystalline structure. In such cases, the conformal protective layer can include an aluminum oxide layer having a density greater 3 g/cm³.

In accordance with additional examples of the disclosure, a method of forming and utilizing a protected metallic component is provided. In accordance with such examples the provided methods include, at a metallic core fabricated from a material selected from the group consisting of titanium, titanium alloys, nickel alloys, stainless steel, and aluminum. The metallic core also includes a non-planar surface. Exemplary methods also include cleaning the non-planar surface to form a clean textured surface, and depositing a conformal protective layer directly on the clean textured surface. In accordance with examples of the disclosure, depositing the conformal protective layer comprises a process selected from a group consisting of a cyclical deposition process, a chemical vapor deposition process, a physical vapor deposition processes, and a spray deposition processes. In accordance with examples of the disclosure, the conformal protective layer is deposited by a cyclical deposition process, the cyclical deposition process comprising, heating the metallic core to a temperature between 100° C. and 500° C., and performing one or more deposition cycles. In such cases, each deposition cycle includes providing a metal precursor to form absorbed metal species on a surface of the metallic core, and providing a reactant to react with the absorbed metal species to form the conformal protective layer on the surface of the metallic core. In accordance with further examples of the disclosure, the methods provided can also include seating the protected metallic component within a reaction chamber, seating a substrate within the reaction chamber, and depositing a layer on a surface of the substrate and on a surface of the protected metallic component thereby forming a parasitic layer on the protected metallic component. In accordance with examples of the disclosure, the methods can also include, extracting the protected metallic component with the parasitic layer thereon from the reaction chamber, and selectively removing the parasitic layer disposed on the protected metallic component. In accordance with examples of the disclosure, selectively removing the parasitic layer includes contacting the conformal protective layer with a selective etchant to remove the conformal protective layer from over the metallic core thereby lifting off the parasitic layer from over the metallic core. In accordance with additional examples of the disclosure, selectively removing the parasitic layer includes contacting the parasitic layer with a selective etchant which etches the parasitic layer selectively relative to the conformal protective layer. In such cases, depositing the conformal protective layer and depositing the parasitic layer are performed within different reaction chambers. In accordance with examples of the disclosure, the selective etchant is selected from a group consisting of sodium hydroxide, and potassium hydroxide.

These and other embodiments will become readily apparent to those skilled in the art from the following detailed description of certain embodiments having reference to the attached figures. The disclosure is not limited to any particular embodiments disclosed.

### BRIEF DESCRIPTION OF DRAWINGS

A more complete understanding of the embodiments of the present disclosure may be derived by referring to the detailed description and claims when considered in connection with the following illustrative figures.

FIG. 1 illustrates a metallic core in accordance with exemplary embodiments of the disclosure.

FIG. 2 illustrates a protected metallic component in accordance with exemplary embodiments of the disclosure.

FIG. 3 illustrate a deposition apparatus including a protected metallic component in accordance with examples of the disclosure.

FIG. 4 illustrates a method for forming a protected metallic component in accordance with exemplary embodiments of the disclosure.

FIG. 5 illustrate a method for utilizing a protected metallic component in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILS DESCRIPTION

The description of exemplary embodiments of methods and structures provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the disclosure provide protected metallic components, deposition apparatus including protected metallic components, and methods for forming and utilizing protected metallic components Exemplary protected metallic components and methods for forming and utilizing protected metallic components can be used to increase the lifetime of the metallic components, prevent damage to the metallic components, and improve the process for removing a parasitic layer formed on the metallic components during a deposition process.

In addition, the protected metallic components of the present disclosure employ a conformal protective layer that enables the selective remove of parasitic layers deposited on the component without damaging the underlying metallic core. In accordance with examples of the disclosure, the conformal protective layers of the present disclosure can operate as an etch-stop layer, thereby preventing the etching of the underlying metallic core of the component during the removal of the parasitic layer. In accordance with further examples of the disclosure, the conformal protective layers of the present disclosure can operate as a sacrificial layer, wherein the conformal protective layer is selectively removed without damaging the underlying metallic core, and by the removal of the conformal protective the parasitic layer deposited thereon is lifted-off and removed from the metallic core of the component.

In this disclosure, gas can include material that is a gas at normal temperature and pressure (NTP), a vaporized solid and/or a vaporized liquid, and can be constituted by a single gas or a mixture of gases, depending on the context.

The terms precursor and reactant can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, the term “wetted region” can refer to a surface or surfaces that are exposed to precursors, reactants, or other process media, within a reaction chamber or a semiconductor processes apparatus.

As used herein, the term “metallic core” can refer to a singular or multiple element component fabricated from a metallic material.

As used herein, the term “titanium alloy” refers to a material or materials comprising elemental titanium alloyed with one or more additional elements.

As used herein, the term “nickel alloy” refers to a material or materials comprising elemental nickel alloyed with one or more additional elements, such as, for example, chromium, molybdenum, and iron. The term “nickel alloys” can also refer to superalloys known by the trademarks Hastelloy™ and Inconel™.

As used herein, the term “stainless steel” refers to a corrosive resistant material or materials comprising elemental iron alloyed with one or more additional elements, such as, for example, chromium, nickel, and carbon.

As used herein, the term “conformal protective layer” and “conformal deposition” can refer a layer which is deposited over a non-planar surface (e.g., a surface including a number vertical feature) with a step coverage greater than 85%, or greater than approximately 90%, or greater than 95%, or greater than 97%, or greater than 98%, or greater than 99%, or substantially equal to 100%, or between 80% and 100%.

As used herein, the term “step coverage” is defined as a percentage ratio of the average layer thickness of a deposited layer disposed on a vertical surface compared to the thickness of the deposited layer disposed on a horizontal surface. In other words, the percentage “step-coverage” can be defined as the average vertical layer thickness of a conformal protective layer: the average horizontal layer thickness of the conformal protective layer.

As used herein, the term “partially crystalline structure” can refer to layer (or material) that comprises a mixture of crystalline regions and non-crystalline regions and the term mixture refers to either segregated or homogeneously integrated crystalline and non-crystalline regions.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

The term cyclic deposition process or cyclical deposition process can refer to the sequential introduction of precursors (and/or reactants) into a reaction chamber to deposit a layer over a substrate and/or a component and includes processing techniques, such as atomic layer deposition (ALD), plasma enhanced atomic layer deposition (PEALD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments.

In this disclosure, any defined meanings do not necessarily exclude ordinary and customary meanings, in some embodiments.

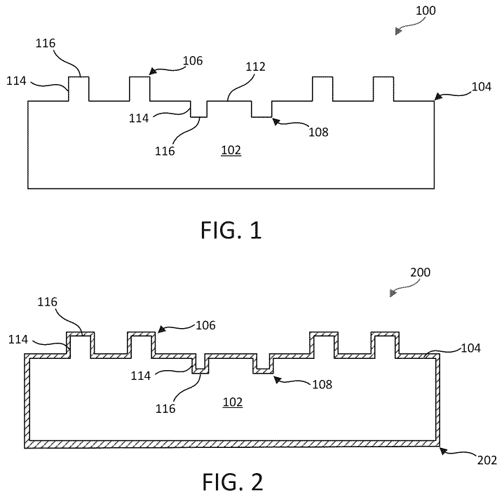

Turning now to the figures, FIG. 1 illustrates a structure 100 including a metallic core 102 prior to depositing a conformal protective layer over a surface of the metallic core in accordance with examples of the disclosure. The metallic core 102 includes a non-planar surface 104 including a number of features 106 and 108.

In accordance with examples of the disclosure, the metallic core 102 can include a single element component or a multi-element component fabricated from a metallic material, or multiple metallic materials. For example, the metallic core can be fabricated from a material selected from a group consisting of titanium, titanium alloys, nickel alloys (including superalloys), stainless steel, and aluminum. As a non-limiting example, the metallic core 102 can include a non-alloyed titanium material comprising a pure unalloyed titanium metal with a composition including less than 0.05 at-% of nitrogen (N₂), less than 0.08 at-% of carbon (C), less than 0.015 atomic-% of hydrogen (H₂), less than 0.50 at-% of iron (Fe), and less than 0.40 at-% of oxygen (O₂). In further examples, the metallic core 102 can include a nickel-based superalloy, such as those commonly sold under the trademarks Haynes™, Hastelloy™, and Inconel™, for example.

In accordance with examples of the disclosure, the metallic core 102 can comprise a number of components that can employed within a wetted region within a reaction chamber, such as, but not limited to, a substrate support assembly, an electrostatic chuck (ESC), a process ring, a chamber wall, a base, a showerhead, a gas distribution plate, a face plate, a liner, a gas line, a shield, a remote plasma source, a flow controller, a flow equalizer, a cooling base, a chamber viewport, a chamber lid, a nozzle, and so on.

As illustrated in FIG. 1, the metallic core 102 includes a non-planar surface 104. The non-planar surface 104 of the metallic core 102 can comprise at least one of nickel, copper, cobalt, chromium, molybdenum, stainless steel, ruthenium, tungsten, platinum, titanium, aluminum, or a mixture thereof. The non-planar surface 104 should not be construed as limited to this list. Other metallic surfaces that may have a naturally occurring native metal oxide or that may readily form a metal oxide upon exposure to certain oxidants (e.g., ozone, water, oxygen) may be suitably used herein as the non-planar surface 104.

In accordance with examples of the disclosure, the non-planar surface 104 can include a number non-planar features, such as one or more raised features and/or one or more recessed features. For example, a raised feature and a recessed feature can include features that are above and below the major plane 112 of the metallic core 102 respectively.

FIG. 1 illustrates an exemplary raised feature 106 and an exemplary recessed feature 108, wherein both exemplary non-planar features 106, 108 have vertical surfaces 114 and horizontal surfaces 116. It should be noted that the vertical surfaces 114 are not necessarily absolutely vertical (i.e., vertical surface 114 do not necessarily need to be at 90° to the major plane 112). Likewise, the horizontal surfaces 116 are not necessarily absolutely horizontal (i.e., horizontal surface 116 do not necessarily need to be at 0° (e.g., parallel) to the major plane 112.

In accordance with examples of the disclosure, the raised/recessed features (106, 108) can have a height/depth greater than 1 μm, greater than 10 μm, greater than 50 μm, greater than 100 μm, greater than 250 μm, greater than 500 μm, greater than 750 μm, greater than 1000 μm, or between 1 μm and 1000 μm. Further, in such examples, the raised/recessed features (106, 108) can have a height/depth greater than 1 mm, greater than 2 mm, greater than 3 mm, greater 4 mm, greater than 5 mm, greater than 10 mm, greater than 20 mm, greater than 30 mm, greater than 50 mm, greater than 100 mm, or between 1 mm and 100 mm.

In accordance with examples of the disclosure, the raised features 106 and the recessed feature 108 can include high aspect ratio features. Such high aspect ratio features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height (or depth) of the feature.

In accordance with examples of the disclosure, the non-planar features (e.g., 106 and 108) can include, but are not limited to pillars, pins, columns, apertures, holes, vias, channels, etc. In exemplary embodiments, the raised features 106 can include vertical pins protruding from a surface of a metallic core comprising a substrate support assembly. In further exemplary embodiments, the recessed features 108 can include apertures indented into a surface of a metallic core comprising a gas distribution plate.

In accordance with examples of the disclosure, the non-planar surface 104 can include a textured surface to assist with adhesion of the subsequently deposited conformal protective layer. In accordance with further examples of the disclosure, the non-planar surface 104 can also include a cleaned textured surface. In such cases, the non-planar surface is free, or substantially free, of oxides, organics, oil, particulates, or other debris and contaminants that could be detrimental to the deposition of the conformal protective layer.

FIG. 2 illustrates an exemplary protected metallic component 200 including a metallic core 102 and a conformal protective layer 202. In accordance with examples of the disclosure, the conformal protective layer 202 has an average layer thickness less than 1000 nm, or less than 500 nm, less than 400 nm, less than 300 nm, less than 250 nm, less than 200 nm, less than 100 nm, less than 50 nm, less than 30 nm, less than 20 nm, less than 10 nm, or less than 5 nm. In accordance with examples of the disclosure, the conformal protective layer 202 has an average layer thickness greater than 5 nm, greater than 10 nm, greater than 20 nm, greater than 30 nm, greater than 50 nm, greater than 100 nm, greater than 200 nm, greater than 250 nm, greater than, 300 nm, greater than 400 nm, greater than 500 nm, or greater than 1000 nm. In accordance with examples of the disclosure, the conformal protective layer 202 has an average layer thickness between 5 nm and 500 nm, between 10 nm and 400 nm, between 15 nm and 350 nm, or between 20 nm and 300 nm. In accordance with further examples of the disclosure, the conformal protective layer 202 has an average layer thickness between 5 nm and 1000 nm, between 10 nm and 750 nm, between 15 nm and 600 nm, or between 20 nm and 500 nm.

In accordance with examples of the disclosure, the conformal protective layer 202 is disposed directly on the non-planar surface 104 of the metallic core 102. In such cases, the conformal protective layer 202 is disposed directly on the non-planar surface 104 with a step coverage greater than 85%, greater than 90%, greater than 92%, greater than 94%, greater than 95%, greater than 96%, greater than 98%, greater than 99%, or even substantially equal to 100%. Further in such cases, the conformal protective layer 202 is disposed directly on the non-planar surface 104 with a step coverage between 85% and 100%, between 90% and 99%, or between 95% and 98%. In such examples, the step-coverage can be determined as a percentage ratio of the average layer thickness of the conformal protective layer disposed on the horizontal surfaces 116 compared with the average layer thickness of the conformal protective layer disposed on the vertical surfaces 114.

In accordance with examples of the disclosure, the conformal protective layer 202 comprises a material selected from a group consisting of metals, metal oxides, and metal carbides. As used herein, the term “metal” and “metals” refer to both to metal elements (e.g., aluminum, zirconium, etc.) and semi-metal elements (e.g., silicon). In further examples, the conformal protective layer can comprise a material not including metallic elements. In further examples, the conformal protective layer can include polymers, such as, fluoropolymers, for example.

In accordance with examples of the disclosure, the conformal protective layer 202 comprises a metal oxide selected from a group consisting of aluminum oxides, zirconium oxides, and tantalum oxides. In such cases, the conformal protective layer 202 has a partially crystalline structure. For example, the conformal protective layer 202 can comprise a mixture of crystalline regions and non-crystalline regions (e.g., amorphous regions). Further, the partially crystalline conformal protective layer can have a polycrystalline structure. In such cases, the structure of the conformal protective layer can be determined by techniques such as, x-ray diffraction, for example.

In accordance with examples of the disclosure, the conformal protective layer 202 can comprise an aluminum oxide layer. In such cases, the aluminum oxide layer can have a density greater than 2.0 g/cm³, greater than 2.5 g/cm³, greater than 3.0 g/cm³, greater than 3.25 g/cm³, greater than 3.5 g/cm³, greater than 3.75 g/cm³, or greater than 3.9 g/cm³. Further, in such cases, the aluminum oxide layer can have a density between 2.0 g/cm³ and 3.9 g/cm³, between 2.5 g/cm³ and 3.75 g/cm³, or between 3.0 g/cm³ and 3.5 g/cm³.

In accordance with examples of the disclosure, the conformal protective layer 202 can comprise a zirconium oxide layer having a density greater than 3.0 g/cm³, greater than 3.5 g/cm³, greater than 4.0 g/cm³, greater than 4.25 g/cm³, greater than 4.5 g/cm³, greater than 5.0 g/cm³, or greater than 5.5 g/cm³. Further, in such cases, the zirconium oxide layer can have a density between 3.0 g/cm³ and 5.5 g/cm³, between 3.5 g/cm³ and 5.0 g/cm³, or between 4.0 g/cm³ and 4.5 g/cm³.

In accordance with additional examples of the disclosure, the conformal protective layer 202 comprises a metal oxide selected from a group consisting of aluminum oxides, silicon oxides, yttrium oxides, and zirconium oxides. In such cases, the conformal protective 202 layer has an amorphous structure. For example, the conformal protective layer 202 can comprise an amorphous layer which does not exhibit, or substantially does not exhibit, long range ordering of the crystal structure. In such cases, the structure of the conformal protective layer can be determined by techniques such as, x-ray diffraction, for example. Additionally, in such cases, the conformal protective layer 202 can include a plurality of pores. For example, the conformal protective layer can have a porosity less than 25%, less than 20%, less than 10%, less than 5%, less than 2%, less 1%, less than 0.8%, or less than 0.5%. Further, in such cases, the conformal protective layer 202 can have a porosity between 0.5% and 25%, or between 0.8% and 15%, or between 1% and 10%.

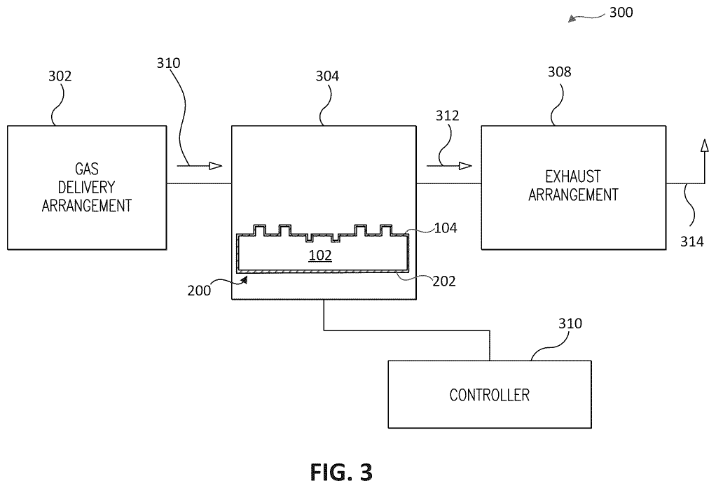

FIG. 3 illustrates a semiconductor processing apparatus 300 in accordance with examples of the disclosure. The semiconductor processing apparatus can comprise a deposition apparatus and includes a gas delivery arrangement 302 and a reaction chamber 304. In accordance with examples of the disclosure, a protected metallic component 200 is disposed within the reaction chamber 304. The semiconductor processing system 300 also includes an exhaust arrangement 308 and a controller 310. Although a particular arrangement of the semiconductor processing system 300 is shown and described herein, it is to be understood and appreciated that semiconductor processing systems having other arrangements can also benefit from the present disclosure.

The gas delivery arrangement 302 is connected to the reaction chamber 304 and is configured to provide one or more precursors/reactants 310 to the reaction chamber 304. The reaction chamber 304 can house a number of protected metallic components disposed therein, as illustrated by the exemplary protected metallic component 200. The exhaust arrangement 308 is connected to the reaction chamber 304, and is fluidly coupled to the protected metallic component 200, and is configured to communicate a flow of residual precursor/reactant and/or reaction products 312 from the reaction chamber 304 to an external environment 314 outside of the semiconductor processing system 300. The controller 310 is operatively connected to the semiconductor processing system and is configured to control deposition of a layer of material.

In accordance with examples of the disclosure, the protected metallic component(s) 200 disposed within the reaction chamber 304 includes a metallic core 102 and a non-planar surface 104, as previously described above and having all the properties, characteristics, and features as described above.

In accordance with examples of the disclosure, the protected metallic component 200 disposed with the reaction chamber 304 includes a conformal protective layer 202 disposed directly on the non-planar surface 104, the conformal protective layer having all the properties, characteristics, and features as described above. In accordance with examples of the disclosure, the conformal protective layer 202 has an average layer thickness between 20 nm and 300 nm, and a step-coverage over the non-planar surface 104 greater than 90%. In accordance with examples of the disclosure, the conformal protective layer is a partially crystalline structure. In such cases, the conformal protective layer 202 is an aluminum oxide layer having a density greater than 3 g/cm³. In further examples, the conformal protective layer 202 is a zirconium oxide layer having a density greater than 5 g/cm³.

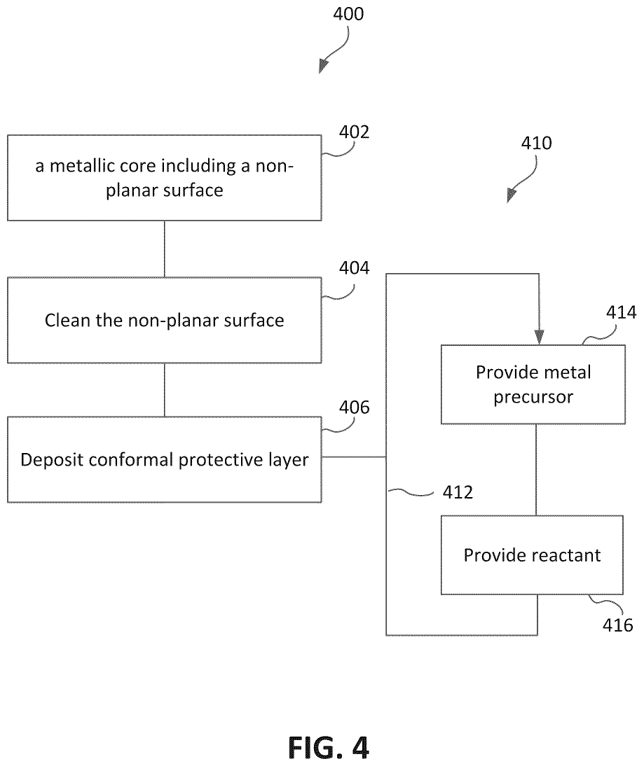

FIG. 4 illustrates a method 400 in accordance with examples of the disclosure. Method 400 includes, at a metallic core fabricated from a material selected from a group consisting of titanium, titanium alloys, nickel alloys, stainless steel, and aluminum, the metallic core including a non-planar surface (step 402), cleaning a surface of the metallic core (step 404), and depositing a conformal protective layer on the metallic core (step 406).

Step 402 employs a metallic core as described previous and includes all the properties and characteristics as described above. In accordance with examples of the disclosure, the metallic core includes a non-planar surface.

In accordance with examples of the disclosure, step 404 includes cleaning the non-planar surface of the metallic core to form a clean textured surface. In accordance with examples of the disclosure, at step 404, prior to depositing the conformal protective coating, the metallic core can be exposed to one or more pre-clean processes. The surfaces of the metallic core can contain oxides, organics, oil, soil, particulate, debris, and/or other contaminants which can removed prior to depositing the conformal protective layer on the metallic core. The pre-clean process can be or include one or more blasting or texturing processes, vacuum purges, a solvent clean, an acid clean, a wet clean, a plasma clean, sonication, or any combination thereof. Once cleaned and/or textured, the subsequently deposited conformal protective layer has stronger adhesion to the surfaces of the metallic core than if otherwise not exposed to the pre-clean process.

In accordance with examples of the disclosure, the non-planar surface (and additional surface) surfaces of the metallic core can be blasted with or otherwise exposed to beads, sand, carbonate, or other particulates to remove oxides and other contaminates therefrom and/or to provide texturing to the surfaces of the metallic core. In such examples, the metallic core can be placed into a chamber within a pulsed push-pull system and exposed to cycles of purge gas (e.g., N₂, Ar, He, or any combination thereof) and vacuum purges to remove debris from the raised and recessed features on the non-planar surface of the metallic core. In other examples, the surfaces of the metallic core can be exposed to hydrogen plasma, oxygen or ozone plasma, and/or nitrogen plasma, which can be generated in a plasma chamber or by a remote plasma system.

In accordance with examples of the disclosure, organic removal or oxide removal, from the surfaces of the metallic core (including the non-planar surface) can include exposing surfaces to a hydrogen plasma, then degassing the surfaces, then exposing the surfaces to an ozone treatment. In other examples, such as for organic removal, the surfaces of the metallic core can be exposed to a wet clean that includes: soaking in an alkaline degreasing solution, rinsing, exposing the surfaces to an acid clean (e.g., sulfuric acid, phosphoric acid, or hydrochloric acid), rinsing, and exposing the surfaces to a deionized water sonication bath. In some examples, such as for oxide removal, the surfaces of the metallic core can be exposed to a wet clean that includes: exposing the surfaces to a dilute acid solution (e.g., acetic acid or hydrochloric acid), rinsing, and exposing the surfaces to a deionized water sonication bath. In one or more examples, such as for particle removal, the surfaces of the metallic core can be exposed to sonication (e.g., megasonication) and/or a supercritical carbon dioxide wash, followed by exposing to cycles of purge gas (e.g., N₂, Ar, He, or any combination thereof) and vacuum purges to remove particles from and dry the surfaces. In some examples, the metallic core can be exposed to heating or drying processes, such as heating the metallic core to a temperature between 50° C. and 150° C. and exposing to surfaces to the purge gas. The metallic core can be heated in an oven or exposed to lamps for the heating or drying processes.

Step 406 includes depositing a conformal protective layer on the cleaned texted surface of the metallic core. In accordance with examples of the disclosure, depositing the conformal protective layer comprises a process selected from a group consisting of a cyclical deposition process, a chemical vapor deposition process, a physical vapor deposition processes, and a spray deposition processes.

In accordance with examples of the disclosure, step 406 includes depositing the conformal protective layer by a cyclical deposition process 410, such as an atomic layer deposition process, for example. The cyclical deposition process 410 can include, heating the metallic core to a deposition temperature, and performing one or more deposition cycles, as illustrated by the loop 412. In such examples, each deposition cycle includes, providing a metal precursor to form absorbed metal species on a surface of the metallic core (step 414), and providing a reactant to react with the absorbed metal species to form the conformal protective layer on the surface of the metallic core (step 416).

During step 406, a metallic core is seated within a reaction chamber. The reaction chamber used during step 406 can be or include a reaction chamber of a chemical vapor deposition reactor system configured to perform a chemical vapor deposition process or a cyclical deposition process. In some embodiments, the reaction chamber used during step 406 can be or include a reaction chamber of an atomic layer deposition reactor system configured to perform a cyclical deposition process. The reaction chamber can be a standalone reaction chamber or part of a cluster tool. The reaction chamber can include a substrate heater to heat the metallic core a deposition temperature.

During step 406, the metallic core can be heated to a temperature (e.g., the deposition temperature) between 100° C. and 500° C., or between 150° C. and 400° C., or between 250° C. and 350° C., or between 275° C. and 325° C., or between 280° C. and 320° C. In some embodiments, the step of depositing the conformal protective layer (step 406) can be performed at a temperature of less than 500° C., or less than 400° C., or less than 300° C., or less than 200° C., or less than 100° C.

In addition to controlling the temperature of the metallic core, a pressure within the reaction chamber may also be regulated. For example, in some embodiments of the disclosure, the pressure within the reaction chamber during step 406 may be less than 760 Torr or between 0.2 Torr and 760 Torr, about 1 Torr and 100 Torr, or about 1 Torr and 10 Torr.

In accordance with examples of the disclosure, the cyclical deposition process 410 includes the steps of providing a metal precursor to form an absorbed metal species on the surface of the metallic core (step 414) and providing a reactant to react with the absorbed metal species (step 416) to form the conformal protective layer on the non-planar surface of the metallic core metal. Steps 414 and 416 can be repeated as illustrated by loop 412, each loop 412 comprising an individual deposition cycle of the cyclical deposition process 410. Further, steps 414 and 416 can be initiated and/or terminated in any order. Yet further, cyclical deposition process 410 can include one or more (e.g., 1-10 or 1-5) steps 414 and/or 416 prior to proceeding to the other of step 414 or 416.

During step 414, a metal precursor is provided to the reaction chamber. The temperature and pressure within the reaction chamber can be as described above in connection with step 406.

In accordance with examples of the disclosure, the metal precursor can include an aluminum precursor selected from a group consisting of AlCl3, Al(OiPr)3, AlEt3, trimethylaluminum (TMA), triethylaluminum (TEA), dimethylaluminum hydride (DMAH), dimethylethylaminealane (DMEAA), trimethylaminealane (TEAA), tritertbutylaluminum (TTBA), and N-methylpyrroridinealance (MPA).

In accordance with additional examples of the disclosure, the metal precursor can include a zirconium precursor selected from a group consisting of Zr(NEtMe)4, ZrCp2(NMe2)2, and Zr(OtBu)4.

In accordance with further examples of the disclosure, the metal precursor can include an yttrium precursor selected from a group consisting of Y(CpBu)3, Y(CpEt)3, Y(EtCp)2(iPr2AMD), Y(iPrAMD)3, Y(thd)3 and Y(CpMe)3.

In accordance with further examples of the disclosure, the metal precursor can include a tantalum precursor selected from a group consisting of Ta(NEt)(NEt2)3 Ta(NEt2)5 Ta(NtBu)(iPrAMD)2(NMe2) Ta(NtBu)(tBu2pz)3 Ta(OEt)4(dmae), Ta(OEt)5, TaCl5, and TaI5.

In accordance with further examples of the disclosure, the metal precursor can include a silicon precursor. In some cases, the silicon precursor comprises a compound having a general formula RₐSiX_{b} or R_{c}X_{d}Si-SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c. R may be a hydrocarbon. If a is two or three, or c is two, each R can be selected independently. In some embodiments, each R is selected from alkyls and aryls. For clarity, X may represent different (e.g., independently selected) ligands. Thus, in some embodiments, the silicon precursor may be, for example, SiH₂Br₂, SiH₂I₂ or SiH₂Cl₂. In some cases, the silicon precursors can consist of silicon and hydrogen. For example, the silicon precursor may comprise a silane, such as, for example, silane (SiH₄), disilane (Si₂H₆), trisilane (Si₃H₈), tetrasilane (Si₄H1₀), or higher order silanes with the general empirical formula SiₓH₍₂ₓ₊₂₎.

A duration of step 414 during each deposition cycle 410 can be between about 0.1 seconds and about 60 seconds, between about 0.1 seconds and about 10 seconds, or between about 0.5 seconds and about 5.0 seconds. A flow rate of the metal precursor to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

During step 416, a reactant is provided to the reaction chamber. Exemplary reactants suitable for use in step 416 can include reducing agents, oxidizing agents, and carbonizing agents. Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), (e.g., C1-C4) alcohols, (e.g., C1-C4) aldehydes, (e.g., C1-C4) carboxylic acids, (e.g., B1-B12) boranes, or an amine. Exemplary oxidizing agents include one or more of water (H₂O), hydrogen peroxide (H₂O₂), ozone (O₃), oxides of nitrogen, such as, for example, nitrogen monoxide (NO), nitrous oxide (N₂O), and nitrogen dioxide (NO₂). In some embodiments of the disclosure, the oxidizer precursor may comprise an organic alcohol, such as, for example, isopropyl alcohol. Exemplary carbonizing agents can include hydrocarbons, such as, propane and/or ethane for example, and metalorganics which can act as both a metal source and a carbon source.

During step 416, a flow rate of the reactant to the reaction chamber can be greater than zero and less than 30 slm, or less than 15 slm, or less than 10 slm, or less than 5 slm, or less than 1 slm, or even less than 0.1 slm. For example, the flow rate can be between about 0.1 to 30 slm, from about 5 to 15 slm, or equal to or greater than 10 slm. In the case of cyclical deposition processes, the reactant can be pulsed—e.g., for a duration between about 0.01 seconds and about 180 seconds, between about 0.05 seconds and about 60 seconds, or between about 0.1 seconds and about 30 seconds.

The metal precursor and/or reactant can be purged from the reaction chamber—e.g., after each pulse and/or upon completion of a step 414, 416 and/or each deposition cycle 410. A purge can be effected either in time or in space, or both. Purging times can be, for example, from about 0.01 seconds to about 20 seconds, from about 0.05 seconds to about 20 seconds, or from about 1 second to about 20 seconds, or from about 0.5 seconds to about 10 seconds, or from about 1 second to about 7 seconds. A flow rate of a purge gas to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

In some embodiments, the metal precursor may be pulsed more than one time, for example two, three or four times, before a reactant is pulsed to the reaction chamber. Similarly, there may be more than one pulse, such as two, three or four pulses, of a reactant before a metal precursor is pulsed (i.e., provided) to the reaction chamber.

The cyclical deposition process (step 410) is repeated until an end criteria is met. For example, the end criteria can be based on a number of deposition cycles 412 performed, or by the desired thickness of the conformal protective layer deposited. The deposited conformal protective layer can have all the properties and characteristics as previously described above.

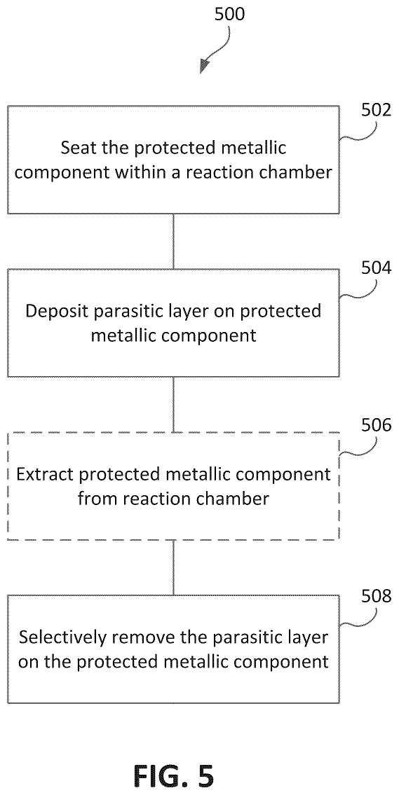

FIG. 5 illustrates an additional method 500 in accordance with examples of the disclosure. Method 500 includes seating the protected metallic component within a reaction chamber (step 502), depositing a layer on a surface of a substrate and on a surface of the protected metallic component thereby forming a parasitic layer on the protected metallic component (step 504), optionally extracting the protected metallic component with the parasitic layer thereon from the reaction chamber (step 506), and selectively removing the parasitic layer disposed on the protected metallic component (step 508).

In accordance with examples of the disclosure, the reaction chamber used during step 502 can be or include a reaction chamber of a chemical vapor deposition reactor system configured to perform a chemical vapor deposition process or a cyclical deposition process. In some embodiments, the reaction chamber used during step 502 can be or include a reaction chamber of an atomic layer deposition reactor system or plasma-enhanced atomic layer deposition reactor system configured to perform a cyclical deposition process. The reaction chamber can be a standalone reaction chamber or part of a cluster tool. The reaction chamber can include a substrate heater to heat a substrate to deposition temperature as well as heating the protected metallic component disposed within the reaction chamber.

Step 504 includes depositing a layer on a surface of a substrate disposed within the reaction chamber and on the surface of the protected metallic component thereby forming a parasitic layer on the protected metallic component. In accordance with examples of the disclosure, depositing the parasitic layer can include chemical vapor deposition processes or cyclic deposition processes, such as, atomic layer deposition processes.

In accordance with examples of the disclosure, the deposited layer and hence the parasitic layer can selected from a group consisting of metals, metal oxides, metal nitrides, metal carbides, metal silicides, and mixtures thereof. In such examples, the deposited layer (and the parasitic layer) can comprise a metal oxide, such as a hafnium oxide, for example. In such cases the parasitic layer can include a hafnium oxide parasitic layer. Further in such cases, the parasitic layer can be deposited directly over the conformal protective layer and not on the metallic core of the protected metallic component. In accordance with examples of the disclosure, the parasitic layer can be deposited to a thickness greater than 10 μm, greater than 25 μm, greater than 50 μm, greater than 100 μm, greater than 250 μm, greater than 500 μm, greater 750 μm, greater than 1000 μm, or greater than 1200 μm. In such case, the parasitic layer can be deposited to a thickness between 10 μm and 1200 μm, between 25 μm and 1000 μm, between 50 μm and 750 μm, or between 100 μm and 500 μm. In accordance with further examples of the disclosure, the parasitic layer can be deposited to a thickness greater than 1 mm, greater than 25 mm, greater than 50 mm, greater than 100 mm, greater than 150 mm, or greater than 200 mm. In such cases, the parasitic layer can be deposited to a thickness between 1 mm and 200 mm, between 25 mm and 150 mm, or between 50 mm and 100 mm.

Step 506 optionally includes extracting the protected metallic component with the parasitic layer thereon from the reaction chamber. In such cases, the protected metallic component is extracted in order to remove the parasitic layer ex-situ, i.e., externally from the reaction chamber. In accordance with examples of the disclosure, the protected metallic component is extracted from the reaction chamber after an extended period of operation within the reaction chamber. In such cases, the protected metallic component can be subjected to a plurality of deposition runs. In alternative examples, the protected metallic component can remain within the reaction chamber and subsequent removal of the parasitic layer can be performed in-situ, i.e., within the reaction chamber where the deposition of the parasitic layer was performed.

Step 508 includes selectively removing the parasitic layer disposed on the protected metallic component.

In accordance with examples of the disclosure, selectively removing the parasitic layer can include contacting the conformal protective layer with a selective etchant to remove the conformal protective layer disposed over the metallic core thereby lifting off the parasitic layer from over the metallic core. In such cases, the protected metallic component is extracted from the reaction chamber and the removal of the parasitic layer is performed ex-situ. In such cases, the conformal protective layer can perform as a sacrificial layer that can be readily removed (without damaging the underlying metallic core) and upon removal, also removes the parasitic layer adhered to the conformal protective layer. In such examples of the disclosure, the selective etchant can comprise an selective alkaline solution. For example, the selective etchant can be selected from a group consisting of sodium hydroxide, and potassium hydroxide. In alternative examples of the disclosure, the selective etchant can comprise a selective acidic solution. Further in such cases, the protected metallic component is contacted with the selective etchant for a time period such that the entire conformal protective layer is removed and with it the parasitic layer. The metallic core can then be cleaned and a further conformal protective layer can be deposited over the a non-planar surface of the metallic core before reinsertion in a reaction chamber.

In accordance with further examples of the disclosure, selectively removing the parasitic layer comprises contacting the parasitic layer with a selective etchant which etches the parasitic layer selectively relative to the conformal protective layer.

In such cases, the conformal protective layer can perform as an etch-stop layer that is etch resistant to the selective etchant employed to remove the parasitic layer. Therefore, the parasitic layer can be removed from over the conformal protective layer without removing a significant portion of the conformal protective layer. Hence, the underlying metallic core is not exposed to the selective etchant as the conformal protective layer completely seals the metallic core from the selective etchant. In such cases, the protected metallic component can be reused within a reaction chamber of a deposition apparatus without the need to redeposit a further conformal protective layer.

In accordance with examples of the disclosure wherein the conformal protective layer is employed as an etch-stop layer, the parasitic layer can be removed in-situ, i.e., without having to extract the protected metallic component from the reaction chamber in which the parasitic layer was deposited. In such cases, the parasitic layer can be removed by exposing the parasitic layer to a selective etchant comprising a vapor phase etchant or a plasma phase etchant. For example, vapor phase etchants and plasmas formed from such vapor phase etchants can include CF₃, NF₃, HF, and ClF3, for example.

In accordance with further examples of the disclosure wherein the conformal protective layer is employed as an etch-stop layer, the parasitic layer can be removed ex-situ, i.e., after extracting the protected metallic component from the reaction chamber in which the parasitic layer was deposited. In such cases, the parasitic layer can be removed by a mechanical process, a chemical process, a laser illumination process, or a combination thereof. In some embodiments, the parasitic layer is selective removed by a selective etchant. In such cases, the selective etchant can comprise an selective alkaline solution. For example, the selective etchant can be selected from a group consisting of sodium hydroxide, and potassium hydroxide. In alternative examples of the disclosure, the selective etchant can comprise a selective acidic solution. Further in such cases, the protected metallic component is contacted with the selective etchant for a time period such that the entire parasitic layer without a significant thickness of the conformal protective layer being removed.

Therefore, in accordance with such examples of the disclosure, the selective etchant is selected from a group consisting of sodium hydroxide, and potassium hydroxide.

In accordance with further examples of the disclosure, depositing the conformal protective layer and depositing the parasitic layer are performed within different reaction chambers.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A protected metallic component for use within a wetted region of the interior of a reaction chamber, the protected metallic component comprising:
a metallic core fabricated from a material selected from a group consisting of titanium, titanium alloys, nickel alloys, stainless steel, and aluminum, the metallic core including a non-planar surface; and
a conformal protective layer disposed directly on the non-planar surface, the conformal protective layer having an average layer thickness between 20 nm and 300 nm and a step-coverage over the non-planar surface greater than 90%.

2. The protected metallic component of claim 1, wherein the conformal protective layer comprises a material selected from a group consisting of metals, metal oxides, and metal carbides.

3. The protected metallic component of claim 2, wherein the conformal protective layer comprises a metal oxide selected from a group consisting of aluminum oxides, zirconium oxides, and tantalum oxides.

4. The protected metallic component of claim 3, wherein the conformal protective layer has a partially crystalline structure.

5. The protected metallic component of claim 4, wherein the conformal protective layer is an aluminum oxide layer having a density greater 3 g/cm³.

6. The protected metallic component of claim 4, wherein the conformal protective layer is a zirconium oxide layer having a density greater 5 g/cm³.

7. The protected metallic component of claim 2, wherein the conformal protective layer comprises a metal oxide selected from a group consisting of aluminum oxides, silicon oxides, yttrium oxides, and zirconium oxides.

8. The protected metallic component of claim 7, wherein the conformal protective layer has an amorphous structure.

9. The protected metallic component of claim 8, wherein the conformal protective layer has a porosity between 1% and 10%.

10. A deposition apparatus including:
a reaction chamber;
a protected metallic component disposed with the reaction chamber, the protected metallic component comprising;
a metallic core fabricated from a material selected from a group consisting of titanium, titanium alloys, nickel alloys, stainless steel, and aluminum, the metallic core including a non-planar surface; and
a conformal protective layer disposed directly on the non-planar surface, the conformal protective layer having an average layer thickness between 20 nm and 300 nm and a step-coverage over the non-planar surface greater than 90%.

11. The deposition apparatus of claim 10, wherein the conformal protective layer has a partially crystalline structure.

12. The deposition apparatus of claim 11, wherein the conformal protective layer is an aluminum oxide layer having a density greater 3 g/cm³.

13. A method of forming and utilizing a protected metallic component, the method comprising:
at a metallic core fabricated from a material selected from a group consisting of titanium, titanium alloys, nickel alloys, stainless steel, and aluminum, the metallic core including a non-planar surface;
cleaning the non-planar surface to form a clean textured surface; and
depositing a conformal protective layer directly on the clean textured surface.

14. The method of claim 13, wherein depositing the conformal protective layer comprises a process selected from a group consisting of a cyclical deposition process, a chemical vapor deposition process, a physical vapor deposition process, and a spray deposition process.

15. The method of any of claim 14, wherein the conformal protective layer is deposited by the cyclical deposition process comprising;
heating the metallic core to a temperature between 100° C. and 500° C.;
performing one or more deposition cycles, wherein each deposition cycle includes;
providing a metal precursor to form absorbed metal species on a surface of the metallic core; and
providing a reactant to react with the absorbed metal species to form the conformal protective layer on the surface of the metallic core.

16. The method of claim 13 further comprising:
seating the protected metallic component within a reaction chamber;
seating a substrate within the reaction chamber;
depositing a layer on a surface of the substrate and on a surface of the protected metallic component thereby forming a parasitic layer on the protected metallic component; and
selectively removing the parasitic layer disposed on the protected metallic component.

17. The method of claim 16, wherein selectively removing the parasitic layer comprises contacting the conformal protective layer with a selective etchant to remove the conformal protective layer from over the metallic core thereby lifting off the parasitic layer from over the metallic core.

18. The method of claim 16, wherein selectively removing the parasitic layer comprises contacting the parasitic layer with a selective etchant which etches the parasitic layer selectively relative to the conformal protective layer.

19. The method of claim 17, wherein the selective etchant is selected from a group consisting of sodium hydroxide, and potassium hydroxide.

20. The method of claim 18, wherein depositing the conformal protective layer and depositing the parasitic layer are performed within different reaction chambers.
